(19) United States
(12) Patent Application Publication
(10) Pub. No.: US 2024/0326087 A1
(43) Pub. Date: Oct. 3, 2024

(54) PROCESS FOR RECTIFYING A POLYMER FILM

(71) Applicant: COMMISSARIAT À L'ENERGIE ATOMIQUE ET AUX ENERGIES ALTERNATIVES, Paris (FR)

(72) Inventors: Pierre MONTMEAT, Grenoble (FR); Franck FOURNEL, Grenoble (FR); Thierry ENOT, Grenoble (FR)

(73) Assignee: COMMISSARIAT À L'ENERGIE ATOMIQUE ET AUX ENERGIES ALTERNATIVES, Paris (FR)

(21) Appl. No.: 18/620,152

(22) Filed: Mar. 28, 2024

(30) Foreign Application Priority Data
Mar. 30, 2023 (FR) 23/03106

(51) Int. Cl. B05D 1/00; B05D 3/02

(52) U.S. Cl. CPC B05D 1/005; B05D 3/0254; B05D 2203/30

(57) ABSTRACT

A method for rectifying a polymer film including the steps of: a) providing a first substrate including a front surface, the front surface having a surface energy less than approximately 22 mJ/m², b) spreading a thermoplastic polymer on the front surface leading to the formation of a polymer film and at least one dewetted zone of the front surface, c) providing a second substrate including a non-stick surface, d) bonding the polymer film and the non-stick surface leading to the formation of a bonding interface having an adhesion energy lower than the adhesion energy between the polymer film and the front surface, e) applying a creep treatment so that the at least one dewetted zone of the front surface is covered by creep of the polymer film, and f) disassembly at the bonding interface so as to obtain the front surface completely covered by the rectified polymer film.

The present invention relates to the field of structures made of semiconductor material for the manufacture of electronic components. In particular, the invention concerns a method for rectifying a polymer film on a low-wetting surface. According to another aspect, the invention proposes a multilayer structure which can be obtained by said method and an intermediate structure which can be obtained during said method.

The methods for manufacturing electronic component often use organic polymers in thin film form. The polymer can be used for different applications:
It can act as a permanent or temporary adhesive
It can act as an electrical insulator
It can protect components by encapsulating them.
It can be used as a masking resin during a photolithography step, etc.

The polymer is generally offered in solution. It is spread in a thin film on a substrate such as a silicon wafer by spin coating. The spreading method results in a covering film that is uniform in thickness. Nonetheless, if the surface on which it is spread is not sufficiently wetting, for example a surface with low surface energy, the polymer dewets and uncovered surface zones are observed. This structure makes it impossible to use the wafer in particular for the aforementioned subsequent methods.

One of the aims of the present invention is to at least overcome the problem of covering a low-wetting surface with a polymer film. To this end, the present invention proposes a method for rectifying a polymer film comprising the steps of:
a) providing a first substrate comprising a front surface, the front surface having a surface energy less than approximately 22 mJ/m²,
b) spreading a thermoplastic polymer on the front surface leading to the formation of a polymer film and at least one dewetted zone of the front surface,
c) providing a second substrate comprising a non-stick surface,
d) bonding the polymer film and the non-stick surface leading to the formation of a bonding interface having an adhesion energy Ea2 lower than the adhesion energy Ea1 between the polymer film and the front surface,
e) applying a creep treatment to the polymer film so that the at least one dewetted zone is covered by the creep of the polymer film, and
f) disassembling the second substrate and the first substrate at the bonding interface so as to obtain the front surface completely covered by the rectified polymer film.

Thus, the method of the invention advantageously uses the ability of creeping thermoplastic polymers to cover by creep the dewetted zones of the low-wetting front surface. The front surface is thus completely covered by the polymer film at the end of step e) or f). The polymer film obtained is continuous. Its exposed surface has a roughness identical to that of the surface of the second substrate. The fact of providing a non-stick surface on the second substrate allows adhesion of low energy Ea2, in particular by the presence of Van der Waals type bond, which allows the mechanical strength of the bonded assembly in step d) but which allows disassembly of step f).

By the term ‘dewetting’ and its derivatives, is meant in this document the meaning used in physical chemistry which reflects the fact that a film deposited on a surface spontaneously withdraws from a zone of said surface leading to reducing the contact area between the surface and the film.

By the expression ‘non-stick surface or film’ is meant a surface or film which ensures low adhesion with an object brought into contact with it, typically an adhesion energy less than or equal to approximately 1100 mJ/m², in particular an adhesion energy less than or equal to approximately 1000 mJ/m² and for example an adhesion energy less than or equal to approximately 900 mJ/m².

According to a possibility, the adhesion energy Ea1 between the front surface and the polymer film and the adhesion energy Ea2 between the polymer film and the non-stick surface respects the following condition Ea1>Ea2+100 mJ/m² so as to be able to easily disassemble the bonding interface in step f) while retaining the polymer film on the first substrate, covering the entire non-stick surface.

According to an arrangement, step b) is carried out by deposition by spin coating of a liquid formulation comprising the thermoplastic polymer on the front surface.

According to a possibility, step b) comprises, after deposition by spin coating, at least one step of applying a heat treatment for the evaporation of one or more solvents from the liquid formulation.

According to another arrangement, step b) is carried out by deposition by spray coating a liquid formulation comprising the thermoplastic polymer on the front surface.

According to a variant, step b) is carried out by dipping at least the front surface in a liquid formulation comprising the thermoplastic polymer.

According to an arrangement, the bonding step d) leads to the formation of an intermediate structure comprising the first substrate bonded to the second substrate with an adhesion energy Ea1.

According to an arrangement, the creep treatment according to step e) is obtained by applying a heat treatment to the polymer film, in particular to obtain a viscosity of the polymer film lower than 10⁴ Pa·s. This viscosity allows the polymer to flow sufficiently to be able to be spread and permanently cover the dewetted zones of the front surface of the first substrate. A multilayer structure comprising a rectified polymer film covering the entire front surface of the first substrate is then obtained.

According to a possibility, the heat treatment is carried out at a temperature T higher than the glass transition temperature Tg of the thermoplastic polymer, and in particular such that T>Tg+100° C. The compliance with this condition guarantees achieving the desired viscosity of the polymer. It can then be spread to cover the dewetted zone(s) of the front surface.

According to an arrangement, the creep treatment according to step e) is carried out under a pressure (or vacuum) of 0.01 Pa. This condition avoids in particular the presence of oxygen during step e) which could lead to the degradation of the polymer film.

According to a particular embodiment of the invention, the step e) of the creep treatment is completed by the application of a compression on the first substrate bonded to the second substrate. This compression is preferably applied in a direction substantially perpendicular to the plane of the bonding interface, in particular with an intensity comprised between 0.02 and 2 MPa, more specifically between 0.1 and 1 MPa for first and second substrates of 200 or 300 mm diameter.

Practically, the compression can be applied directly in a thermocompression bonding machine.

Concretely, the step f) of disassembly comprises the application of a mechanical stress to the bonding interface between the polymer film and the non-stick surface, such as the insertion of a corner, of a blade at the interface, or a jet of fluid, etc.

Alternatively, the mechanical stress is exerted by application of a tensile and/or shear force, or curvature force to the structure obtained in step e).

According to an arrangement, the front surface of the first substrate has a high topography, for example linked to the presence of pillars of a few tenths of micrometers in diameter over a height of a few micrometers or a few tens of micrometers.

According to a possibility, the second substrate comprises a rigid wafer and a non-stick film forming the non-stick surface.

By rigid wafer is meant a wafer which has the same rigidity properties as the first substrate.

Concretely, the material of the rigid wafer is selected from silicon, germanium, glass, sapphire, SiC, GaAs, InP, LNO or LTO.

According to an exemplary embodiment, the non-stick film is formed by deposition on the rigid wafer.

According to a possibility, the non-stick film is obtained from compounds selected from organosilylated compounds, such as OTS supplied by Sigma Aldrich, fluoropolymers, such as the ‘Novec™ 1720 EGC’ polymer (for Electronic Grade Coating) from 3M™, the Optool supplied by the company DAIKIN and the polymer ‘Novec™ 2702 EGC’ (for Electronic Grade Coating) from 3M™. One of the compounds is deposited by spin coating until a non-stick film with a thickness of approximately 5 nanometers is obtained on the rigid wafer.

According to a particular embodiment of the invention, the non-stick film is obtained by placing a sheet of non-stick material on said rigid wafer, such as a sheet of UPILEX-S polyimide or Teflon/PTFE. Said sheet preferably has a sufficient thickness to be self-supporting, in particular a few tens of micrometers. For example, the UPILEX-S polyimide or Teflon/PTFE sheet has a thickness of approximately 50 micrometers

According to this particular arrangement, step f) comprises the separation between the rigid wafer and the polymer film bonded to the first substrate, then the peeling of the sheet of non-stick material from the polymer film.

According to a possibility, the second substrate is a Teflon wafer, notably having a thickness of a few tens of mm, so as to guarantee the mechanical resistance necessary for carrying out step f) of disassembly. Of course, the Teflon wafer alone constitutes the second substrate and the non-stick surface.

Advantageously, the method comprises, before the step b), a trimming step comprising the removal of material from the front surface of the first substrate so as to form a recess in an annular peripheral region of the first substrate. The recess makes it possible to accommodate any possible overflow of the thermoplastic polymer in step e) of creep.

According to an arrangement, the annular peripheral region extends along the peripheral periphery of the first substrate.

According to a possibility, the recess has a width L comprised between approximately 0.5 and 3 mm.

According to an arrangement, the recess has a height H comprised between 50 to 250 micrometers. The dimensions of the recess are variable depending on the risks of overflow of the thermoplastic material in the creep state, and therefore on the quantity of thermoplastic material deposited in step b). If the overflow is controlled, trimming is not necessary, not to mention that depending on the case, the overflow can be managed by subsequent cleaning.

Concretely, the trimming step is simple to implement and can be carried out using a diamond trimming saw or a lapping machine. This method is inexpensive and makes it possible to obtain great homogeneity in the removal of peripheral material. The width L of the trimming is obtained with a variation of only 10 microns and the height H with a variation of only 1 to 2 microns.

According to another possibility, the trimming of step c) is carried out by a photolithography step followed by an ion etching or chemical etching step. This method allows precise homogeneity in dimensions of width L and height H of less 10 than 1 micrometer.

According to a variant, step e) of creep treatment is concomitant with step d) of bonding between the polymer film and the non-stick surface.

According to another possibility, the method further comprises after step f)
a step g) of bringing the polymer film, covering the front surface of the first substrate, into contact with a front face of a third substrate so as to obtain a bonding with an adhesion energy Ea3,
a technological step h) carried out on a rear face of the third substrate, opposite the front face, in particular a thinning by lapping followed by mechanical-chemical polishing, and
a step of disassembling i) of the first substrate having an adhesion energy with the polymer film Ea1<Ea3, so as to recover the third substrate.

The bonding of the polymer film with the third substrate is a strong bond, presenting a high adhesion energy Ea3, and in all cases, greater than Ea1.

This method is particularly advantageous in the case where it is not possible to spread the polymer film on the third substrate.

According to a second aspect, the invention proposes a multilayer structure comprising a polymer film covering the entire front surface of a first substrate, the front surface having a surface energy lower than approximately 22 mJ/m². This multilayer structure allows the realization of numerous subsequent method steps, particularly in the field of manufacturing electronic components.

Preferably, the polymer film is made of thermoplastic polymer.

According to other characteristics, the invention includes one or more of the following optional characteristics considered alone or in combination:
The adhesion energy Ea1 between the polymer film and the front surface is less than 0.9 J/m² and in particular less than 0.5 J/m² and for example approximately 0.2 J/m².
The front surface of the first substrate has a surface energy less than approximately 20 mJ/m², in particular less than approximately 18 mJ/m² and for example less than approximately 16 mJ/m².
The adhesion energy Ea2 between the polymer film and the non-stick surface is comprised between approximately 0.05 J/m² and 0.1 J/m².
The polymer film has a thickness comprised between 15 and 120 micrometers.
The front surface comprises a high topography, such as a structured surface, and/or having low surface energy.
The first substrate is made of semiconductor material such as silicon, germanium, glass, sapphire, SiC, GaAs, InP, LNO or LTO.
The thermoplastic polymer is selected from BrewerBOND® 305 available from the supplier Brewer Science, TWM12000 available from the supplier TOK and a polymer whose viscosity is less than 10⁴ Pa·s from a determined temperature.
The front surface of the first substrate has a structure consisting of pillars with a height comprised between 3 and 10 micrometers.
The trimming step is carried out before or after the structuring step of the front surface.
The pillars notably have a generally square cross section.
The dimensions of the cross section are comprised between 3 and 8 micrometers.
The front surface has a structure comprising pillars of 5 micrometers on a side over a height of 5 micrometers with an inter-pillar spacing of 10 micrometers. At the end of step f) the polymer film extends at least over the entire upper surface of all the pillars of the front surface.
At the end of step f), the lateral sides and the bottom surface of the trenches delimited by the pillars are partially covered with polymer.
The front surface of the first substrate having a surface energy less than 22 mJ/m² consists of a layer deposited on a substrate.
The non-stick film forming the non-stick surface of the second substrate has a thickness comprised between 1 and 10 nanometers.

According to yet another aspect, the present invention proposes an intermediate structure comprising the multilayer structure as previously described and a second substrate, the polymer film being bonded to a non-stick surface of the second substrate with an adhesion energy Ea2 lower than the energy adhesion Ea1 between the polymer film and the front surface of the first substrate, and in particular Ea1>Ea2+100 mJ/m².

Other aspects, aims and advantages of the present invention will appear better on reading the following description of the different embodiments thereof, given by way of non-limiting example and made with reference to the appended drawings. The figures do not necessarily respect the scale of all the represented elements so as to improve their readability. In the remainder of the description, for the sake of simplification, identical, similar or equivalent elements of the different embodiments bear the same numerical references.

Moreover, all the adhesion energies described in this document are determined by the double lever technique with imposed displacement (corner insertion method or Maszara method, well known to those skilled in the art). The attached figures are:

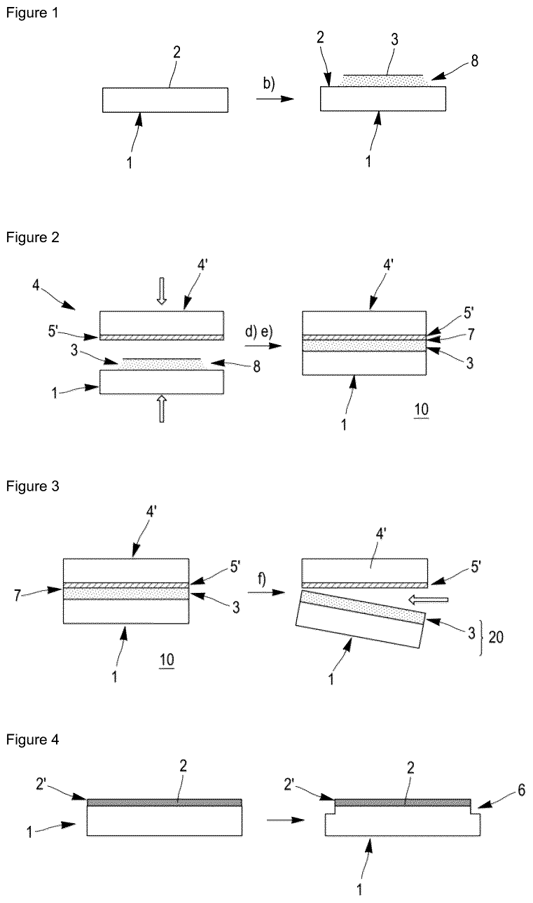

FIG. 1 illustrates steps a) and b) of the method according to an embodiment of the invention.

FIG. 2 illustrates steps c) to e) of the method according to the embodiment of FIG. 1.

FIG. 3 illustrates step f) of the method according to the embodiment of FIG. 2.

FIG. 4 illustrates step a) and the trimming step of the method according to a second embodiment of the invention.

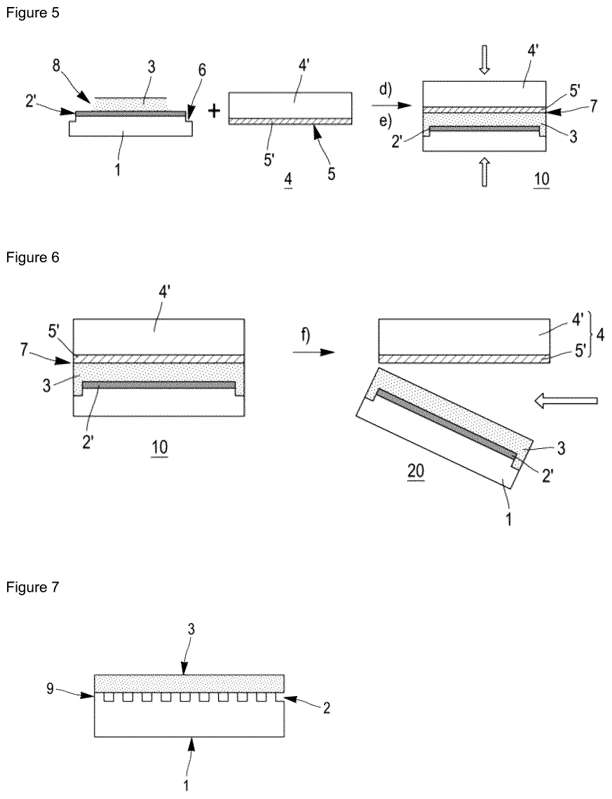

FIG. 5 illustrates steps b) to e) of the method according to a second embodiment of the invention.

FIG. 6 illustrates step f) of the method according to the second embodiment of the invention.

FIG. 7 illustrates a multilayer structure in which the front surface is structured according to another embodiment of the invention.

FIGS. 1 to 3 illustrate the principle of the rectification method according to the invention which makes it possible to cover the entirety of a non-stick or low-wetting surface with a first substrate (surface energy less than approximately 22 mJ/m²) by a polymer film from a liquid formulation of a thermoplastic polymer.

With reference to FIG. 1, a first substrate 1 whose front surface 2 is low-wetting is provided (step a), its surface energy is less than 20 mJ/m². A liquid formulation of a polymer film 3 consisting of a thermoplastic polymer is deposited by spin coating on the front surface 2 (step b-adhesion energy Ea1). If necessary, heat treatments are carried out in order to evacuate the solvents from the liquid formulation after deposition. A dewetting of the polymer film 3 is observed, it leads to the formation of one or more dewetted zones 8 of the front surface 2.

FIG. 2 illustrates the provision according to step c) of a second substrate 4 having a non-stick surface 5. As can be seen in this particular embodiment, the second substrate 4 is formed of a rigid wafer 4′ and of a non-stick film 5′ placed on the surface, the latter forming the non-stick surface 5. Then according to step d), the polymer film 3 is bonded to the non-stick film 5′ to form an intermediate structure 10, the non-stick film 5′ being selected so that the adhesion energy Ea1 between the polymer film 3 and the first substrate 1 is greater than the adhesion energy Ea2 between the polymer film 3 and the non-stick film 5′. Typically, the adhesion energy Ea1 is at least greater than Ea2+0.1 J/m².

A step e) of applying a creep treatment is then carried out by thermocompression. To do this, a sufficiently high compression and temperature are applied to the intermediate structure 10. The temperature T of the thermocompression step is in particular much higher than the glass transition temperature Tg of the thermoplastic polymer (T>Tg+100° C.). Under these conditions, the polymer film 3 becomes fluid, it flows and fills the dewetted zones 8 of the front surface 2, the creep and filling of the dewetted zones being guaranteed when the viscosity of the polymer 3 is less than 10⁴ Pa·s.

As illustrated in FIG. 3, the application of a mechanical constraint, such as the insertion of a corner in the bonded intermediate structure 10, makes it possible to disassemble the bonding interface 7 which has the lowest adhesion energy Ea2, namely the interface between the polymer film 3 and the non-stick surface 5 of the second substrate 4. Thus, the method of the invention makes it possible to rectify the polymer film 3 on a low-wetting front surface 2 and to obtain a multilayer structure 20 which can be used in subsequent steps of manufacturing electronic components.

According to a possibility not illustrated, replacing the non-stick film 5′ placed on the rigid wafer 4′, a non-stick sheet (e.g. a UPILEX-S polyimide sheet) is inserted between the surface of the polymer film 3 and the rigid wafer 4′.

According to yet another variant not illustrated, the second substrate 4 is a Teflon wafer which intrinsically has a non-stick surface 5.

### DETAILED IMPLEMENTATION EXAMPLES

The following examples are produced using silicon substrates 1, 4 of 300 mm in diameter.

### EXAMPLE 1

According to a possibility illustrated in FIG. 4, the first substrate 1 is cut using a diamond saw so as to form a recess 6 in the annular peripheral region of the front surface 2 over a width L of 1.5 mm and a depth (or height H) of 200 μm. Then a fluorinated layer 2′ of Novec™ 1720 is deposited on a first silicon substrate 1 so as to form the low-wetting front surface 2 (FIG. 4).

A thermoplastic polymer of BrewerBOND® 305 is then spread with a thickness of 40 μm on the front surface 2 so as to form the polymer film 3. A dewetting of the polymer 3 is observed. The adhesion energy Ea1 between the polymer film 3 in BrewerBOND® 305 and the front surface 2 in Novec™ 1720 is 0.2 J/m².

On a rigid silicon wafer 4′, a non-stick film 5′ of octadecyltrichlorosilane (OTS) is deposited from a solution of OTS in isooctane leading to obtaining the second substrate 4 and its non-stick surface 5 (FIG. 5). Once brought into contact according to step d), the adhesion energy Ea2 between the polymer film 3 in BrewerBOND® 305 and the non-stick surface 5 in OTS is 0.07 J/m². The first and second substrates 1, 4 are then placed at a temperature of 250° C., under a compression of 0.28 MPa, a pressure (or a vacuum) of 0.01 Pa for a period of 20 min (steps d) and e). These conditions lead to the creep of the polymer film 3 made of BrewerBOND® 305, which fills the dewetted zones 8 of the front surface 2 (step e). The intermediate structure 10 thus obtained is then disassembled at the bonding interface 7 between the polymer film 3 of BrewerBOND® 305 and the fluorinated non-stick surface 5 by inserting a corner (FIG. 6). The final multilayer structure 20 is obtained: the polymer film 3 in BrewerBOND@ 305 is rectified, it covers the entire front surface 2 of the first substrate 1.

### EXAMPLE 2

According to a variant not illustrated, a fluorinated layer 2′ of Novec™ 1720 is deposited on a first silicon substrate 1 so as to form a low-wetting front surface 2. The first substrate 1 is then cut with a diamond saw to form a recess 6 with a width of 2 mm and a depth of 100 μm.

A thermoplastic polymer of BrewerBOND® 305 is then deposited to form a polymer film 3 with a thickness of 20 μm on the low-wetting front surface 2 (step b). A dewetting of the polymer film 3 is observed. The adhesion energy Ea1 between the polymer film 3 in BrewerBOND® 305 and the front surface 2 in Novec™ 1720 is 0.2 J/m².

The first substrate 1 is bonded with a rigid silicon wafer 4′ on which is placed a sheet 5′ of 50 μm UPILEX-S polyimide, which acts as a non-stick surface 5 between the two substrates 1, 4 (step d). The creep treatment (step e) is carried out by applying a temperature of 250° C., with a compression of 0.28 MPa, a vacuum of 0.01 Pa over a period of 20 min. These conditions lead to the creep of the polymer film 3 which fills the dewetted zones 8 of the front surface 2 (step e). The adhesion energy Ea2 between the polymer film 3 and the sheet 5′ of UPILEX-S is very low, for example <0.05 J/m². A corner is inserted into the intermediate structure 10 to disassemble the rigid wafer 4′ then the UPILEX-S sheet is peeled from the surface of the polymer film 3. The obtained multilayer structure 20 includes the rectified polymer film 3, covering the entire front surface 2 (in Novec™ 1720) of the first substrate 1.

According to another variant not illustrated, a Teflon/PTFE sheet of a few tens of micrometers is used instead of the UPILEX-S sheet.

According to an alternative, a single Teflon wafer of few tens of millimeters thick is used to replace the second substrate 4 or the rigid wafer 4′ and the non-stick sheet 5′.

According to yet another alternative, a press with a Teflon-coated head is used instead of the second substrate having a non-stick surface (not illustrated). This Teflon press is also used to apply the compression treatment. In this exemplary embodiment, the first substrate will advantageously be held in place, in particular by a suction table, when the head is raised. This variant advantageously allows grinding to be carried out on several substrates simultaneously.

### EXAMPLE 3

According to yet another variant not illustrated, a first silicon substrate 1 is cut with a diamond saw to form a recess 6 with a width of 3 mm and a depth of 250 μm.

A layer 2′ of perfluorodecyltrichlorosilane (FDTS: CI3Si(CH2) 2 (CF2) 7CF3) is deposited on the first cut-out substrate 1, in order to create the low-wetting front surface 2. A 100 μm TWM12000 polymer film 3 is then deposited on the front surface 2 (step b). A dewetting of the thermoplastic polymer film 3 is observed. The adhesion energy Ea1 between the polymer film 3 in TWM12000 and the front surface 2 in FDTS is 0.9 J/m².

A silicon wafer 4′ is in parallel covered with a non-stick film 5′ of Optool so as to provide the second substrate 4. Bringing it into contact with the polymer film 3 leads to obtaining the intermediate structure 10 and an energy adhesion Ea2 less than 0.1 J/m².

The creep treatment is then carried out by applying a heat treatment at a temperature of 240° C. with a compression of 0.23 MPa, under a vacuum of 0.01 Pa for a duration of 20 min. These conditions lead to the creep of the thermoplastic polymer film 3 which fills the dewetted zones 8 of the front surface 2 (step e). A corner is inserted into the structure 10 and the second substrate 4 is disassembled, the final multilayer structure 20 including the rectified polymer 3, covering the entire front surface 2 is obtained (step f).

### EXAMPLE 4

According to a variant illustrated in FIG. 7, the method comprises before step a) a step of photolithography/etching of the front surface 2 of the first silicon substrate 1 so as to structure the surface 2 by creating pillars 9 of lateral dimensions of 5 micrometers by 5 micrometers and a height of 5 micrometers as well, leading de facto to a low-wetting front surface 2. Step b) consists of depositing a thermoplastic polymer of BrewerBOND® 305 to form a polymer film 3 of 20 micrometers thick, which leads to a dewetted zone 8 on the front surface.

A second substrate 4 is provided. It comprises a rigid silicon wafer 4′ covered by a non-stick fluorinated film 5′ of Novec™ 1720 which forms the non-stick surface 5 (step c). The polymer film 3 is brought into contact with the non-stick surface 5 then the creep treatment is applied by carrying out a heat treatment at 250° C. accompanied by a compression of 0.28 MPa under a vacuum of 0.01 Pa for a duration of 20 minutes (step d) and e)). The creep of the thermoplastic polymer film 3 makes it possible to fill the dewetted zones 8 of the front surface 2 (step e). The insertion of a corner at the interface 7 between the polymer film 3 and the non-stick surface 5 allows the disassembly of the second substrate 4 and the obtaining of the multilayer structure 20 in which the polymer film 3 ground in BrewerBOND® 305 covers the entire structured front surface 2 of the first substrate 1, as illustrated in FIG. 7.

Also illustrated, the recess obtained by trimming the first substrate 1 acts as a reservoir for the thermoplastic polymer which flows. This makes it possible to avoid its overflow from the multilayer structure 20. As seen previously, this trimming step can be omitted if there is no risk of overflow (in the case for example of a very thin layer of polymer film 3) or if the overflow can be managed by subsequent cleaning.

According to another aspect not illustrated in the figures, the polymer film 3 covering the front surface 2 of the first substrate 1 obtained in step f) is brought into contact according to step g) with a front face of a third substrate for a strong bonding, presenting an adhesion energy Ea3>Ea1. Steps for producing electronic circuits h) can thus be applied to the third substrate, such as thinning by CMP mechanical chemical polishing, deposition, photolithography, etc. thanks to the presence of the first substrate 1 which serves as a handle. Then the first substrate 1 having weak adhesion with the polymer film 3 is disassembled (step i) so as to recover the third substrate. This is particularly advantageous in the case where it is not possible to spread the polymer film 3 on the third substrate.

Thus, the present invention proposes a method that is simple to implement and making it possible to rectify a polymer film 3 on a low-wetting surface 2 of a substrate 1 which can be used in a large number of subsequent steps for the manufacture of electronic compounds.

1-10. (canceled)

11. A method for rectifying a polymer film comprising the steps of:
a) providing a first substrate comprising a front surface, the front surface having a surface energy less than approximately 22 mJ/m²,
b) spreading a thermoplastic polymer on the front surface leading to the formation of a polymer film and at least one dewetted zone of the front surface,
c) providing a second substrate comprising a non-stick surface,
d) bonding the polymer film and the non-stick surface leading to the formation of a bonding interface having an adhesion energy lower than the adhesion energy between the polymer film and the front surface,
e) applying a creep treatment to the polymer film so that the at least one dewetted zone of the front surface is covered by the creep of the polymer film, and
f) disassembly of the second substrate and the first substrate at the bonding interface so as to obtain the front surface completely covered by the rectified polymer film.

12. The method for rectifying a polymer film according to claim 11, wherein the creep treatment according to step e) is obtained by applying a heat treatment to the polymer film so that the film polymer reaches a viscosity lower than 10⁴ Pa·s.

13. The method for rectifying a polymer film according to claim 11, wherein step e) of the creep treatment is completed by applying a compression to the first substrate bonded to the second substrate.

14. The method for rectifying a polymer film according to claim 11, wherein step f) of disassembling comprises the application of a mechanical stress to the bonding interface between the polymer film and the non-stick surface.

15. The method for rectifying a polymer film according to claim 11, wherein the second substrate comprises a rigid wafer and a non-stick film, the non-stick film forming the non-stick surface.

16. The method for rectifying a polymer film according to claim 15, wherein the non-stick film is obtained by placing a sheet of non-stick material on said rigid wafer.

17. The method for rectifying a polymer film according to claim 11, wherein the second substrate is a Teflon wafer.

18. The method for rectifying a polymer film according to claim 11, which comprises before step b) a trimming step comprising the removal of material from the front surface of the first substrate so as to form a recess in an annular peripheral region of the first substrate.

19. A multilayer structure comprising a rectified polymer film covering the entire front surface of a first substrate, the front surface having a surface energy lower than approximately 22 mJ/m².

20. An intermediate structure comprising the multilayer structure according to claim 19 and a second substrate, the polymer film being bonded to a non-stick surface of the second substrate with an adhesion energy lower than the adhesion energy between the polymer film and the front surface of the first.
